(19) United States
(12) Patent Application Publication
(10) Pub. No.: US 2014/0306727 A1
(43) Pub. Date: Oct. 16, 2014

(54) FACILITY AND A METHOD FOR TESTING SEMICONDUCTOR DEVICES

(71) Applicant: SAMSUNG ELECTRONICS CO., LTD., Suwon-si (KR)

(72) Inventors: Kyungsook Lee, Daejeon (KR); Jongpil Park, Asan-si (KR); Kwon-Bon Koo, Asan-si (KR); Moon-Seok Kim, Suwon-si (KR); Byoungjun Min, Asan-si (KR)

(73) Assignee: SAMSUNG ELECTRONICS CO., LTD., Suwon-si (KR)

(21) Appl. No.: 14/146,119

(22) Filed: Jan. 2, 2014

(30) Foreign Application Priority Data
Apr. 15, 2013 (KR) 10-2013-0041166

(51) Int. Cl. G01R 31/26; G01R 31/3187

(52) U.S. Cl. CPC G01R 31/26; G01R 31/3187
USPC 324/750.3; 324/756.07

(57) ABSTRACT

A test facility may be used to test semiconductor devices. The test facility may include a stacker part configured to communicate with a server, wherein the server includes test programs for testing semiconductor devices, and a plurality of test board parts disposed in the stacker part, at least one of the test board parts including semiconductor devices disposed thereon and configured to provide at least one of the test programs from the server to the semiconductor devices. The stacker part may include unit stackers which include shelves configured to hold the plurality of test board parts and a stacker controller configured to communicate with the test board parts in the unit stackers and the server.

### CROSS-REFERENCE TO RELATED APPLICATION

This U.S. non-provisional patent application claims priority under 35 U.S.C. §119 to Korean Patent Application No. 10-2013-0041166, filed on Apr. 15, 2013, in the Korean Intellectual Property Office, the disclosure of which is incorporated by reference herein in its entirety.

### TECHNICAL FIELD

The inventive concept relates to a facility and a method for testing a variety of semiconductor devices.

### DISCUSSION OF THE RELATED ART

As information communication technology advances, the use and demand of nonvolatile memory devices are rapidly increasing. A NAND flash memory device, which is an example of a nonvolatile memory device, is being used in portable products, such as cellular or smart phones, cameras, and memory sticks. Capacity and speed of the NAND flash memory devices are continually being increased. A test facility can be used to test the reliability of the NAND flash memory devices.

### SUMMARY

Exemplary embodiments of the inventive concept provide a test facility and a method capable of performing a test process efficiently.

Exemplary embodiments of the inventive concept provide a test facility and a method capable of efficiently performing a series of test processes including a board test process.

According to exemplary embodiments of the inventive concept, a test facility for testing semiconductor devices may include a stacker part configured to communicate with a server, wherein the server may include test programs for testing semiconductor devices, and a plurality of test board parts disposed in the stacker part, at least one of the test board parts including semiconductor devices disposed thereon and configured to provide at least one of the test programs from the server to the semiconductor devices. The stacker part may include unit stackers, which may include shelves configured to hold the plurality of test board parts, and a stacker controller configured to communicate with the test board parts in the unit stackers and the server.

The test facility may further include a power supply part configured to supply a power voltage to the test board parts and the stacker part, wherein the stacker part may further include: power supply boards disposed in the shelves and connected to the power supply part; and backplane boards connected to the power supply boards and the test board parts.

The stacker part may further include stacker boards connected between the stacker controller and the backplane boards.

The stacker boards and the power supply boards may be connected to a first side of the backplane boards, and the test board parts may be connected to a second side of the backplane boards opposite to the first side.

The stacker part may further include: a test controller mounted on at least one of the stacker boards and connected to the stacker controller; and at least one programmable logic device mounted on the stacker board and controlled by the test controller, the programmable logic device configured to provide the test program to the semiconductor devices on the at least one test board part.

The stacker part may further include: a first voltage converter disposed on the power supply board and configured to convert the power voltage into a first voltage; and a second voltage converter disposed on the power supply board and configured to convert the power voltage into a second voltage higher than the first voltage.

The stacker part may further include a voltage converter disposed on the at least one stacker board and configured to convert the first voltage and the second voltage into a control voltage and provide the control voltage to the test controller and the programmable logic device.

The at least one test board part may include: a test board on which the semiconductor devices are disposed; and a plurality of unit sockets configured to connect the test board to the semiconductor devices.

The at least one test board part may include: a controller board disposed on the test board; a test controller disposed on the control board; and at least one programmable logic device disposed on the control board and controlled by the test controller to provide the test program to the semiconductor devices.

The at least one test board part may further include: a local area network (LAN) card disposed on the test board and configured to communicate with the stacker controller; and a vector memory configured to store the test program provided from the test controller.

The stacker part may further include: as robot configured to transport the test board parts between the stackers; and a loader/unloader configured to hold the test board parts prior to being transported by the robot.

At least one of the semiconductor devices is configured to perform a built-in self-test.

According to exemplary embodiments of the inventive concept, a method of testing semiconductor devices may include loading a test board part, on which semiconductor devices having a built-in self-test function may be mounted, into a stacker part, providing a test program from a server to the test board part, performing the built-in self-test on the semiconductor devices, and outputting a test result obtained from the built-in self-test of the semiconductor devices to the server.

The method may further include providing information about the semiconductor devices mounted on the test board part from the stacker part to the server.

Providing the information about the semiconductor devices may include requesting the server to provide the test program.

The method may further include unloading the test board part from the stacker part.

According to an exemplary embodiment of the inventive concept, a test facility for testing semiconductor devices may include: a stacker part configured to receive test programs from a server; first and second test boards disposed in the stacker part, the first test board including first semiconductor devices configured to perform a first built-in test, the second test board including second semiconductor devices configured to perform a second built-in test, wherein the first and second built-in tests are performed at the same time in response to the test programs received from server.

The first and second semiconductor devices may be different from each other.

The first and second test boards may be independently operated.

The stacker part may further include a loader/unloader configured to hold the first and second test boards, a robot configured to move the first and second test boards to a unit stacker and a stacker controller configured to interface between the server and stacker part.

### BRIEF DESCRIPTION OF THE DRAWINGS

The above and other features of the inventive concept will become more clearly understood by describing in detail exemplary embodiments thereof with reference to the accompanying drawings.

FIGS. 1 and 2 are a plan view and a sectional view illustrating a test facility according to an exemplary embodiment of the inventive concept.

FIG. 3 is a sectional view illustrating an internal structure of a unit stacker of FIG. 2, according to an exemplary embodiment of the inventive concept.

FIG. 4 is a plan view illustrating power supply boards and test board parts of FIG. 3, according to an exemplary embodiment of the inventive concept.

FIG. 5 is a plan view illustrating stacker boards and test board parts of FIG. 3, according to an exemplary embodiment of the inventive concept.

FIGS. 6 and 7 are plan views illustrating power supply boards, a stacker part, and test board parts of a test facility according to an exemplary embodiment of the inventive concept.

FIGS. 8 and 9 are plan views illustrating an application of FIGS. 6 and 7, according to an exemplary embodiment of the inventive concept.

FIG. 10 is a block diagram illustrating a connection structure between circuit components of FIG. 7, according to an exemplary embodiment of the inventive concept.

FIG. 11 is a flow chart illustrating a test method according to exemplary embodiments of the inventive concept.

FIG. 12 is a diagram illustrating an interface between a server, a stacker controller, and first and second test controllers of FIG. 10, according to an exemplary embodiment of the inventive concept.

### DETAILED DESCRIPTION OF THE EMBODIMENTS

Hereinafter, exemplary embodiments of the inventive concept will be described more fully with reference to the accompanying drawings. The inventive concept may, however, be embodied in many different forms and should not be construed as being limited to the embodiments set forth herein. In the drawings, the thicknesses of layers and regions may be exaggerated for clarity. Like reference numerals in the drawings may denote like elements, and thus their description may be omitted.

It will be understood that when an element is referred to as being “connected” or “coupled” to another element, it can be directly connected or coupled to the other element or intervening elements may be present.

As used herein, the singular forms “a,” an and “the” are intended to include the plural forms as well, unless the context clearly indicates otherwise.

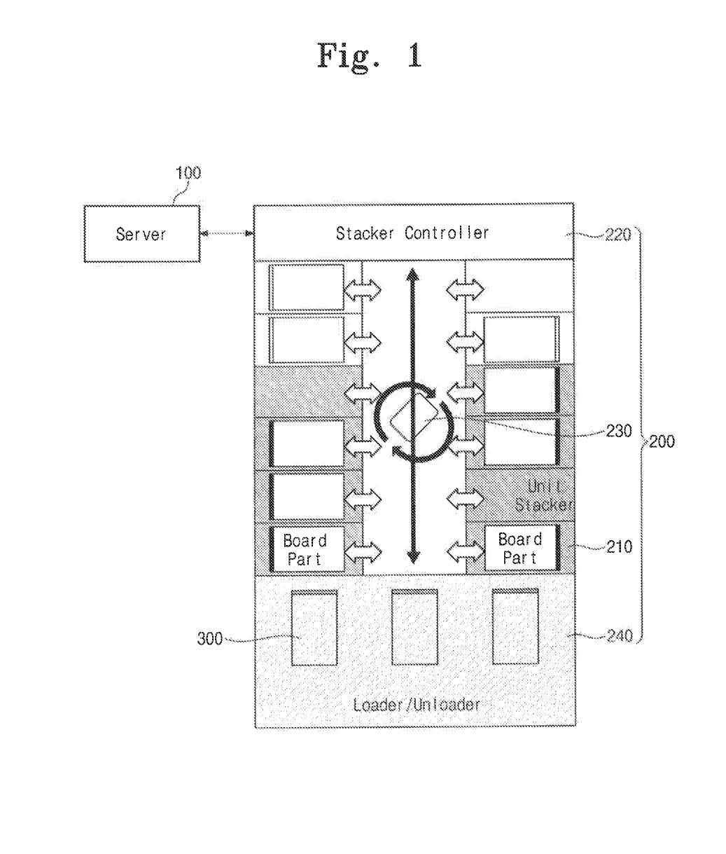

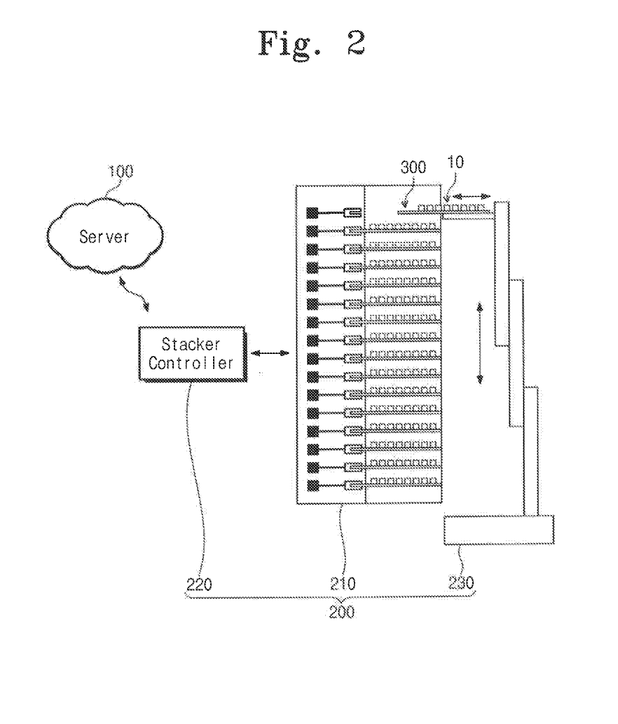

FIGS. 1 and 2 illustrate a test facility according to an exemplary embodiment of the inventive concept. According to an exemplary embodiment of the inventive concept, a test facility may include a server 100, a stacker part 200, and test board parts 300. The server 100 may control overall operations (e.g., logistical management and process) in a semiconductor fabrication facility. For example, the logistical management and process may include a test process performed on semiconductor devices 10. The test board part 300 may be configured to mount a plurality of the semiconductor devices 10. The semiconductor devices 10 may be configured to perform a built-in self-test (BIST) process. The server 100 may provide test programs stored in a database to the semiconductor devices 10. Each of the semiconductor devices 10 may download a test program suitable for their particular function or performance. The server 100 may be configured to effectively control test processes on a variety of semiconductor devices 10.

The stacker part 200 may be provided between the server 100 and the test board parts 300. The server 100 may obtain information about the semiconductor devices 10 in the test board parts 300, from the stacker part 200. The stacker part 200 may include unit stackers 210, a stacker controller 220, a robot 230, and a loader/unloader 240. The unit stackers 210 may be configured to store a plurality of the test board parts 300. For example, each of the unit stackers 210 may be configured to store about sixteen test board parts 300 along a vertical direction. The server 100 may communicate with the stacker controller 220. The stacker controller 220 may control the unit stackers 210, the robot 230, and the loader/unloader 240. The server 100 may perceive the test board parts 300 in the unit stackers 210. The robot 230 may transport the test board parts 300 between the unit stackers 210 and the loader/unloader 240. The unit stackers 210 may be arranged in a row along a moving path of the robot 230. The test board parts 300 may be loaded into the unit stackers 210 by the robot 230. In the loader/unloader 240, the test board parts 300 may be temporarily held in a standby state. The loader/unloader 240 may serve as a waiting position for loading or unloading procedures.

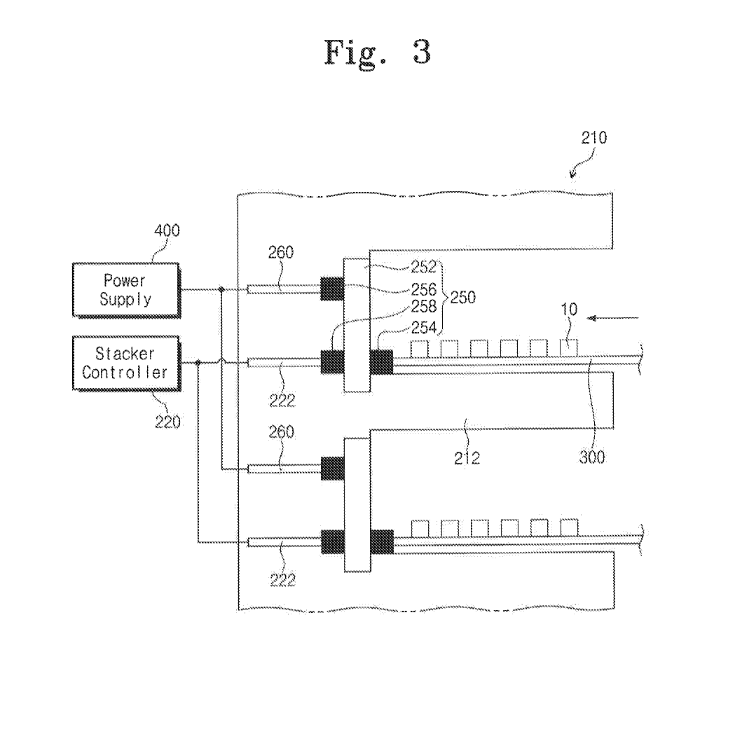

FIG. 3 illustrates an internal structure of the unit stacker 210 of FIG. 2, according to an exemplary embodiment of the inventive concept. The test board parts 300 may be laid on shelves 212 of the unit stackers 210. Stacker boards 222, backplane board parts 250, and power supply boards 260 may be mounted on the shelves 212. The stacker boards 222 may connect the stacker controller 220 to the backplane board parts 250. The backplane board parts 250 may be connected to the test board parts 300. The power supply boards 260 may be connected to a power supply part 400. The power supply part 400 may provide a power voltage to the stacker controller 220 and the test board parts 300 via the power supply boards 260.

The backplane board part 250 may include a backplane board 252, a test board socket 254, a power supply board socket 256, and a stacker board socket 258. The backplane board 252 may be disposed between the power supply boards 260 and the test board parts 300. The test board socket 254 may be mounted on a surface of the backplane board 252. The test board socket 254 may connect the backplane board 252 to the test board parts 300. The backplane board 252 and the test board parts 300 may be disposed to be perpendicular to each other. The power supply board socket 256 and the stacker board socket 258 may be mounted on the other surface of the backplane board 252. The power supply boards 260, the stacker boards 222, and the test board parts 300 may be horizontally disposed.

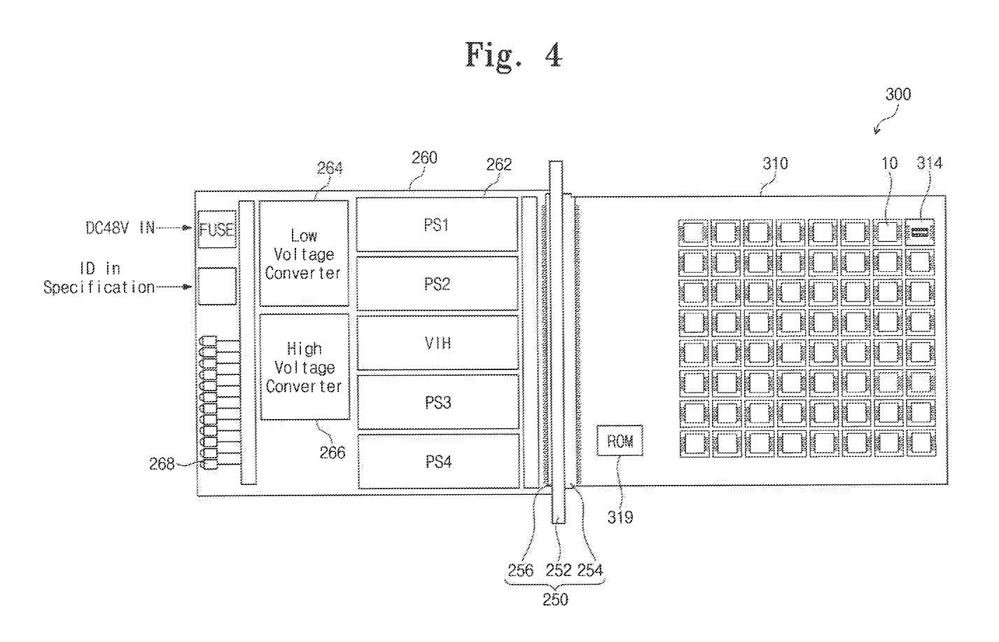

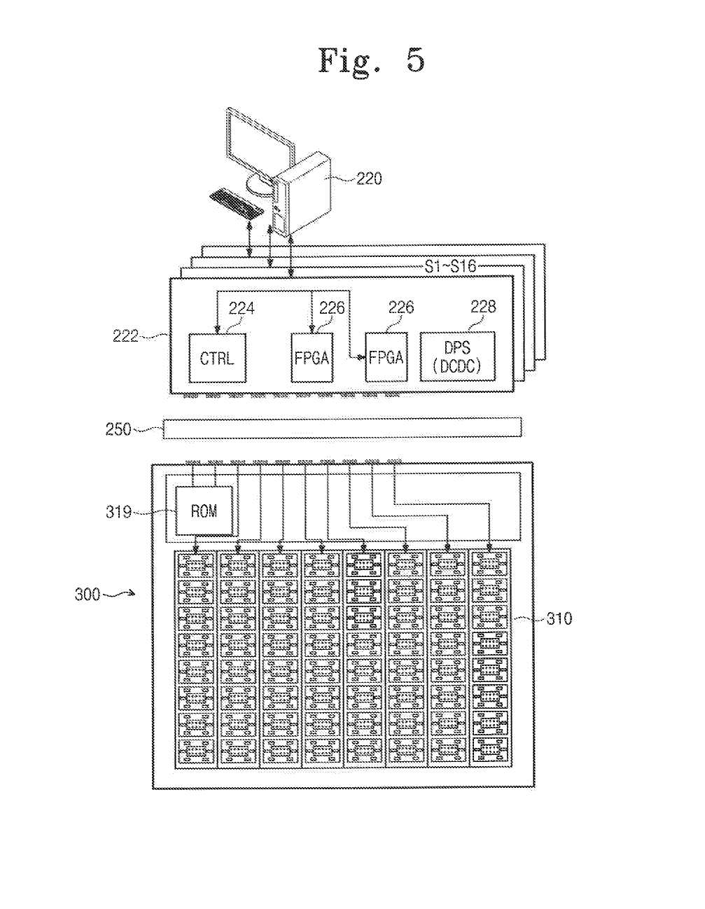

FIG. 4 illustrates the power supply boards 260 and the test board parts 300 of FIG. 3, according to an exemplary embodiment of the inventive concept. FIG. 5 illustrates the stacker boards 222 and the test board parts 300 of FIG. 3, according to an exemplary embodiment of the inventive concept. Referring to FIGS, 3 through 5, first device power supply parts 262, a low voltage converter 264, a high voltage converter 266, and a display part 268 may be mounted on the power supply board 260. The power supply part 400 may supply a power voltage to the low voltage converter 264, the high voltage converter 266, and the first device power supply parts 262. The low voltage converter 264 and the high voltage converter 266 may convert the power voltage into a low voltage and a high voltage, respectively. The power supply part 400 may output a signal of power software (e.g., PWR S/W) to the power supply board. The signal of power software is related to the high voltage and the low voltage. The low voltage and the high voltage may be supplied to the stacker boards 222 and the test board parts 300. In exemplary embodiments of the inventive concept, the power supply part 400 may supply a DC voltage of 48V (e.g., DC48V IN). The low voltage converter 264 may be configured to convert the DC voltage into a low voltage of 5V. The high voltage converter 266 may be configured to convert the DC voltage into a high voltage of 12V. The first device power supply parts 262 may supply a test voltage to the semiconductor devices 10. A plurality of the first device power supply parts 262 (e.g., PS1, PS2, VIH, PS3, PS4) may be arranged in a row on the power supply boards 260. The display part 268 may be configured to display a power supply status of the test board part 300.

The test board part 300 may include a test board 310, test sockets 314, a supplementary memory 319 (e.g., read only memory (ROM)). The test sockets 314 may be mounted on the test board 310. The test board 310 may be configured to have a plurality of pin holes (not shown). The test sockets 314 may be inserted into the pin holes. Further, the semiconductor devices 10 may be mounted on the test sockets 314. For example, the test board 310 may be configured to mount about 64 semiconductor devices 10. The 64 semiconductor devices 10 may be arranged to have an 8×8 matrix. The supplementary memory 319 may be configured to store information about the test board 310.

A first test controller 224, first complex programmable logic devices 226 (e.g., a field programmable gate array (FPGA)), and a first DC/DC converter 228 may be mounted on the stacker board 222. In exemplary embodiments of the inventive concept, 16 stacker boards 222 (S1-S16) may be provided, as shown in FIG. 5. Information about the semiconductor devices 10 of the test board parts 300 may be provided to the first test controller 224. The first complex programmable logic devices 226 may be controlled by the first test controller 224. The first DC/DC converter 228 may be configured to supply a direct current (DC) voltage to the first test controller 224 and the first complex programmable logic devices 226. The first test controller 224 may provide a test program to the first complex programmable logic, devices 226. The first complex programmable logic devices 226 may provide the test program to each of the semiconductor devices 10. The semiconductor devices 10 may perform the BIST. Results of the BIST performed by the semiconductor devices 10 may be provided to the first test controller 224. The stacker controller 220 and the server 100 may receive information about the semiconductor devices 10 of the corresponding test board part 300 from the first test controller 224. Accordingly, the use of the test facility, according to the current embodiment of the inventive concept, makes it possible to effectively perform the test process on the semiconductor devices 10.

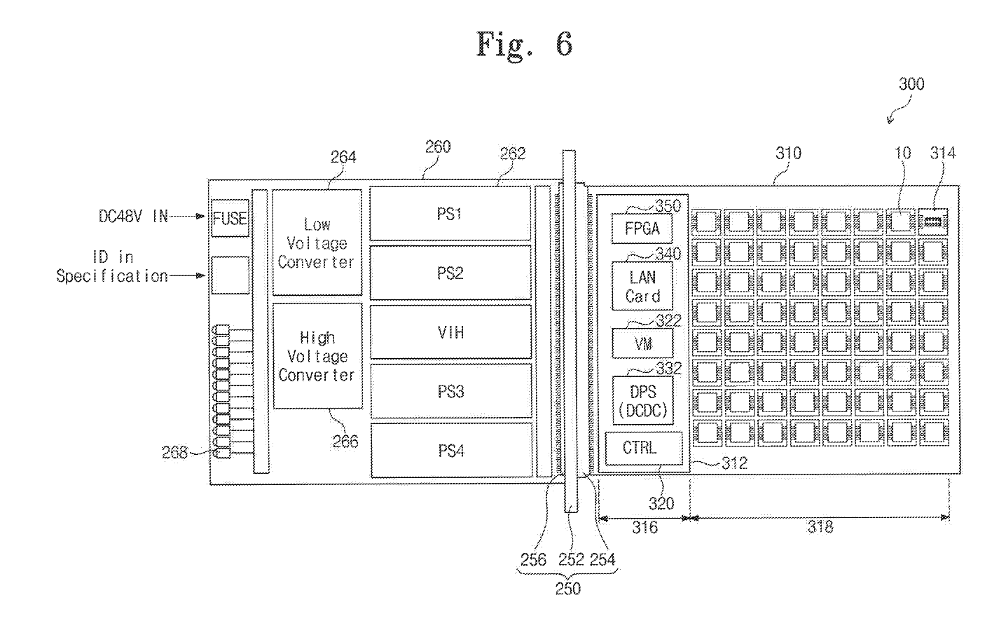

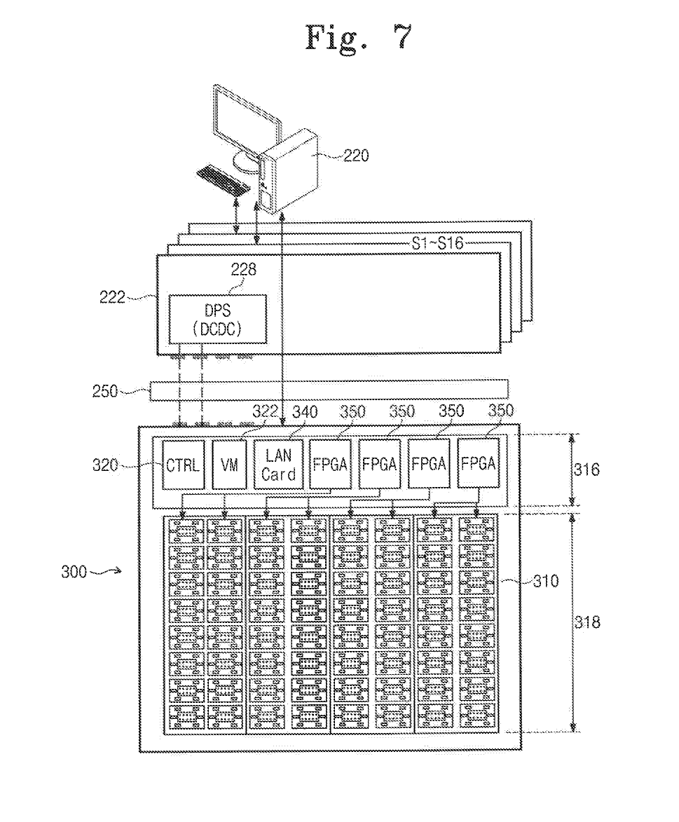

FIGS. 6 and 7 illustrate the power supply boards 260, the stacker boards 222, and the test board parts 300 of the test facility, according to an exemplary embodiment of the inventive concept. According to the exemplary embodiment of the inventive concept shown in FIGS. 6 and 7, the first test controller 224 and the first complex programmable logic devices 226 of the stacker part 200 shown in FIG. 5 may be replaced with a second test controller 320 and second complex programmable logic devices 350 of the test board parts 300. For the sake of brevity, the elements and features of the exemplary embodiment of FIGS. 6 and 7 that are similar to those previously shown and described will not be described in much further detail.

Referring to FIGS. 1 through 3, 6, and 7, the test board parts 300 may include the test board 310, a control board 312, the second test controller 320, a vector memory 322, a local area network (LAN) card 340, and the second complex programmable logic devices 350. The control board 312 and the test sockets 314 may be mounted on the test board 310. The test board 310 may include a control region 316 and a test region 318. The control board 312 may be mounted on the control region 316, while the test sockets 314 may be mounted on the test region 318. The control region 316 may be provided adjacent to the backplane board parts 250. The semiconductor devices 10 may be mounted on the test region 318 of the test board 310 with the test sockets 314. For example, the test board 310 may be configured to mount about 64 semiconductor devices 10. The 64 semiconductor devices 10 may be arranged to have an 8×8 matrix. The second test controller 320, the vector memory 322, a second DC/DC converter 332, the LAN card 340, and the second complex programmable logic devices 350 may be mounted on the control board 312. The first DC/DC converter 228 may be mounted on the stacker board 222. The first DC/DC converter 228 may supply a control voltage to the second test controller 320.

Information about the semiconductor devices 10 in the test board part 300 may be provided to the second test controller 320. The vector memory 322 may be configured to store information on position, status, performance, and/or test result of each of the semiconductor devices 10. The LAN card 340 may connect the second test controller 320 to the stacker controller 220. The second test controller 320 may provide information about the semiconductor devices 10 to the stacker controller 220 and the server 100. If a test program for the semiconductor devices 10 is provided from the stacker controller 220 and the server 100, the second complex programmable logic devices 350 may provide the test program to each of the semiconductor devices 10. The semiconductor devices 10 may perform the BIST. Results of the BIST performed by the semiconductor devices 10 may be monitored by the second test controller 320.

Unlike that shown in FIG. 6, the test board parts 300 may provide test power directly to the semiconductor devices 10. In this case, the first device power supply parts 262 may not be mounted on the power supply board 260. Further, the test board parts 300 may provide control power directly to the second test controller 320. In this case, the first DC/DC converter 228 may not be mounted on the stacker board 222.

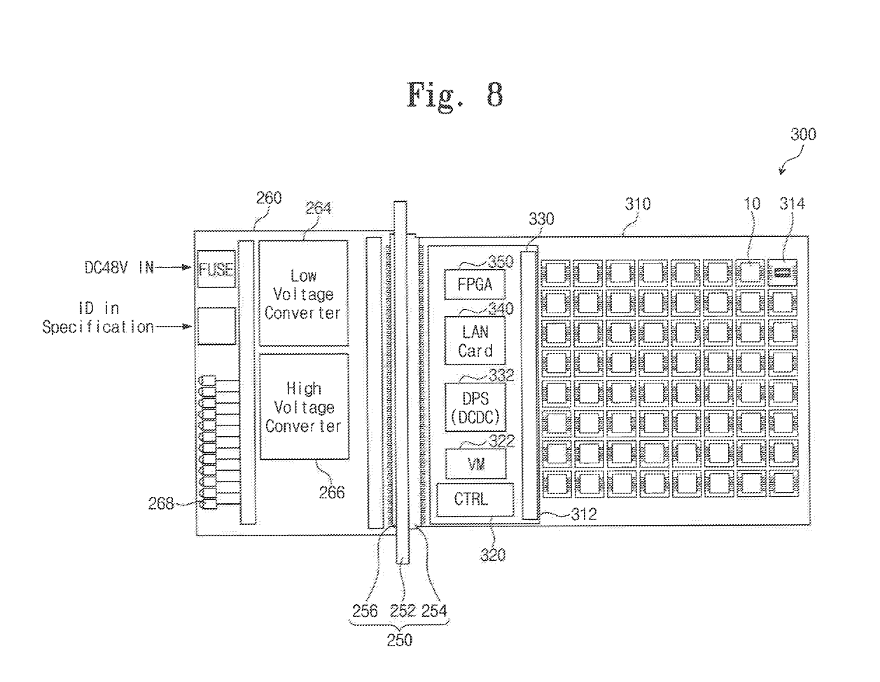

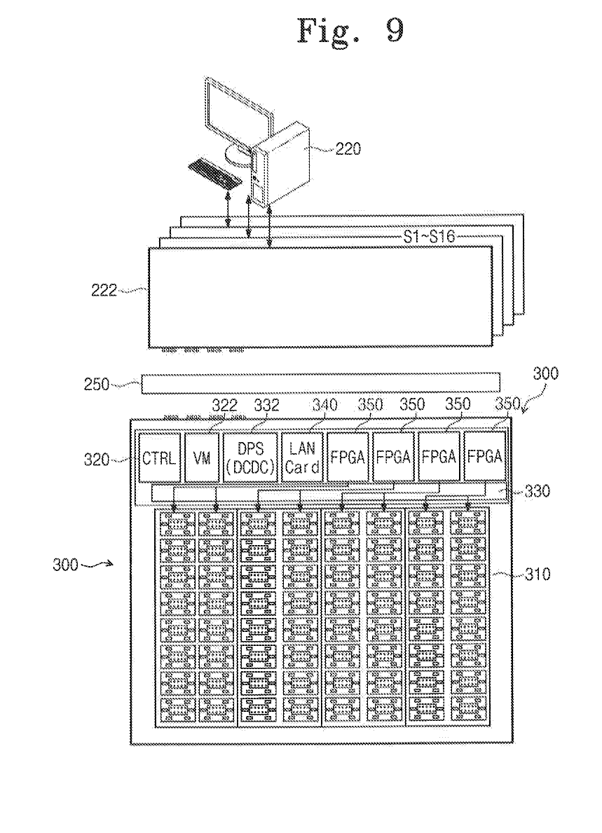

FIGS. 8 and 9 illustrate an application of FIGS. 6 and 7, according to an exemplary embodiment of the inventive concept. A second device power supply part 330 and a second DC/DC converter 332 may be mounted on the control board 312 of the test board part 300. The second device power supply part 330 may supply the test voltage to the semiconductor devices 10. The second DC/DC converter 332 may supply the control voltage to the second test controller 320. The low voltage converter 264, the high voltage converter 266, and the display part 268 may be mounted on the power supply board 260. The low voltage converter 264 and the high voltage converter 266 may supply the low voltage and the high voltage to the second device power supply part 330 and the second DC/DC converter 332, respectively.

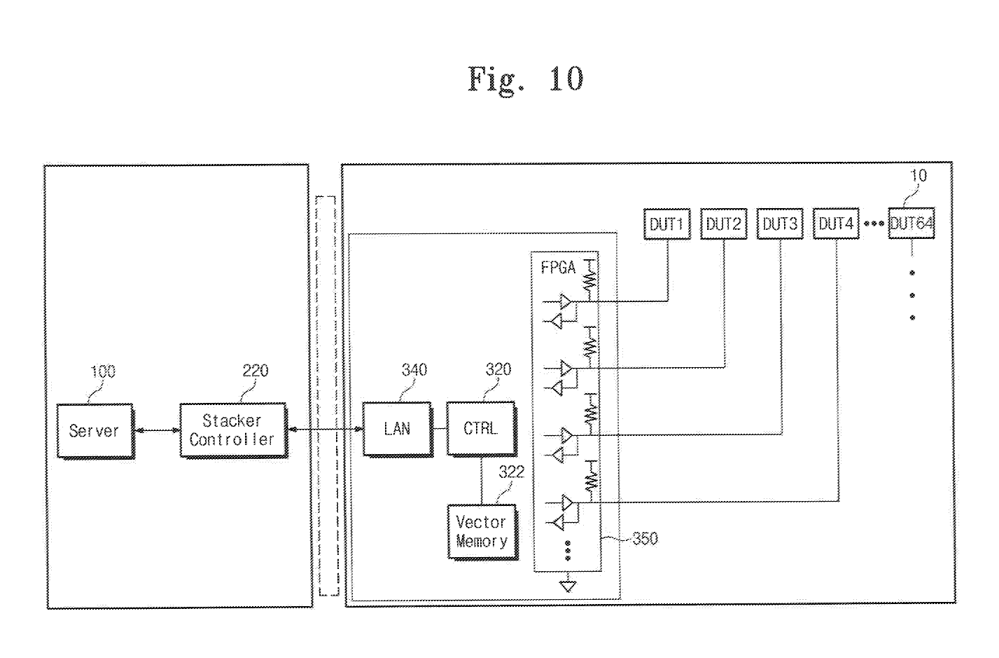

FIG. 10 illustrates a connection structure between circuit components of FIG. 7, according to an exemplary embodiment of the inventive concept. The server 100 may be coupled to the second test controller 320 via the stacker controller 220 and the LAN card 340. The second complex programmable logic devices 350 may be coupled between the second test controller 320 and the semiconductor devices 10. The second test controller 320 may provide information about the semiconductor devices 10 to the server 100. The server 100 may provide the test program to the second test controller 320. The second test controller 320 may store the test program in the vector memory 322. The second complex programmable logic devices 350 may provide the test program to each of the semiconductor devices 10. The semiconductor devices 10 may perform the BIST. Accordingly, the use of the test facility, according to the exemplary embodiment of the inventive concept shown in FIGS. 6 and 7, makes it possible to effectively perform the test process on the semiconductor devices 10.

A test method, in which the test facilities according to exemplary embodiments of the inventive concept are used, will be described hereinafter.

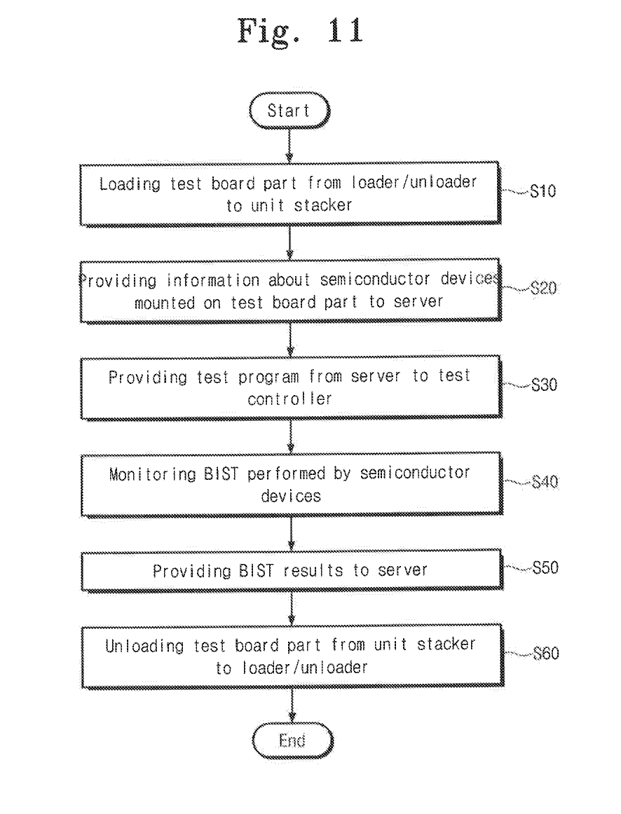

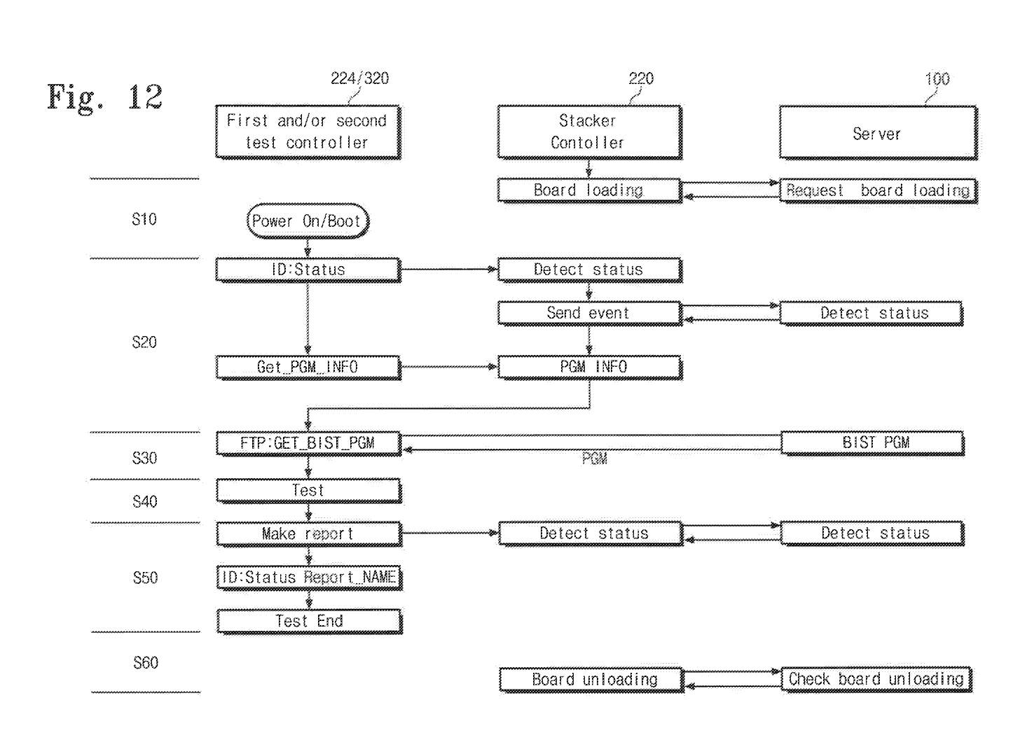

FIG. 11 illustrates a test method according to exemplary embodiments of the inventive concept. FIG. 12 is a diagram illustrating an interface between the server 100, the stacker controller 220, and the first and second test controllers 224 of FIG. 5 and 320 of FIG. 10, according to an exemplary embodiment of the inventive concept. First, the test board part 300 may be loaded into the unit stacker 210 from the loader/unloader 240 by the robot 230 (in S10). The loading of the test board part 300 may be monitored by the stacker controller 220. Board loading may be requested by the stacker controller 220 to the server 100.

Thereafter, the first test controller 224 or the second test controller 320 may provide information about the semiconductor devices 10 mounted on the test board part 300 to the server 100 (in S20). In other words, a status of each of the semiconductor devices 10 may be monitored by the server 100. For example, the first or second test controller 224 or 320 may detect and then send the status, such as an ID of the semiconductor devices 10, to the server 100. Further, the first test controller 224 or the second test controller 320 may request the server 100 to provide the test program for the semiconductor devices 10 (e.g., Get_PGM_INFO, as shown in FIG. 12).

The server 100 may provide the test program (e.g., PGM in FIG. 12) to the first test controller 224 or the second test controller 320 (in S30). The first test controller 224 or the second test controller 320 may download the test program to the semiconductor devices 10. The first complex programmable logic devices 226 and the second complex programmable logic devices 350 may provide the test program to each of the semiconductor devices 10.

The first test controller 224 or the second test controller 320 may monitor the BIST performed by the semiconductor devices 10 (in S40). The semiconductor devices 10 may perform the BIST in response to a control signal from the first test controller 224 or the second test controller 320.

If the BIST is finished, the first test controller 224 or the second test controller 320 may provide results of the BIST performed by the semiconductor devices 10 to the server 100 (in S50). The server 100 may examine whether a failure occurs in each of the semiconductor devices 10. This may correspond to Detect Status in FIG. 12.

Thereafter, the robot 230 may unload the test board part 300 from the unit stacker 210 to the loader/unloader 240 (in S60). The server 100 may classify the semiconductor devices 10 into good and bad devices and manage the semiconductor devices 10 based on the classification.

In the above description, the test board 300 is described to be a printed circuit board, but exemplary embodiments of the inventive concept may not be limited thereto. For example, the test board 300 may be a unit board. Further, in the above description, the semiconductor devices 10 are described to be NAND flash memory devices, but exemplary embodiments of the inventive concept may not be limited thereto. For example, the semiconductor devices 10 may be a memory module, a graphic card, an audio card, a LAN card, or a mainboard for mobile devices, in which at least one volatile memory device is provided.

According to exemplary embodiments of the inventive concept, the server 100 may provide the test program to the semiconductor devices 10. The semiconductor devices 10 may perform the BIST using the test program downloaded therein. Accordingly, the test facility according to an exemplary embodiment of the inventive concept allows an operator to test a variety of semiconductor devices.

Further, the use of the test facility makes it possible to perform the test process with efficiency. For example, a series of test processes including a board test process can be efficiently performed.

While the inventive concept has been particularly shown and described with reference to exemplary embodiments thereof, it will be understood by one of ordinary skill in the art that variations in form and detail may be made therein without departing from the spirit and scope of the inventive concept as defined in the attached claims.

What is claimed is:

1. A test facility for testing semiconductor devices, comprising:
a stacker part configured to communicate with a server, wherein the server includes test programs for testing semiconductor devices; and
a plurality of test board parts disposed in the stacker part, at least one of the test board parts including semiconductor devices disposed thereon and configured to provide at least one of the test programs from the server to the semiconductor devices,
wherein the stacker part comprises:
unit stackers which include shelves configured to hold the plurality of test board parts; and
a stacker controller configured to communicate with the test board parts in the unit stackers and the server.

2. The test facility of claim 1, further comprising a power supply part configured to supply a power voltage to the test board parts and the stacker part,
wherein the stacker part further comprises:
power supply boards disposed in the shelves and connected to the power supply part; and
backplane boards connected to the power supply boards and the test board parts.

3. The test facility of claim 2, wherein the stacker part further comprises stacker boards connected between the stacker controller and the backplane boards.

4. The test facility of claim 3, wherein the stacker boards and the power supply hoards are connected to a first side of the backplane boards, and
the test board parts are connected to a second side of the backplane hoards opposite to the first side.

5. The test facility of claim 3, wherein the stacker part further comprises:
a test controller mounted on at least one of the stacker boards and connected to the stacker controller; and
at least one programmable logic device mounted on the stacker board and controlled by the test controller, the programmable logic device configured to provide the test program to the semiconductor devices on the at least one test board part.

6. The test facility of claim 5, wherein the stacker part further comprises:
a first voltage converter disposed on the power supply board and configured to convert the power voltage into a first voltage; and
a second voltage converter disposed on the power supply board and configured to convert the power voltage into a second voltage higher than the first voltage.

7. The test facility of claim 6, wherein the stacker part further comprises a voltage converter disposed on the at least one stacker board and configured to convert the first voltage and the second voltage into a control voltage and provide the control voltage to the test controller and the programmable logic device.

8. The test facility of claim 1, wherein the at least one test board part comprises:
a test board on which the semiconductor devices are disposed; and
a plurality of unit sockets configured to connect the test board to the semiconductor devices.

9. The test facility of claim 8, wherein the at least one test board part further comprises:
a controller board disposed on the test board;
a test controller disposed on the control board; and
at least one programmable logic device disposed on the control board and controlled by the test controller to provide the test program to the semiconductor devices.

10. The test facility of claim 9, wherein the at least one test board part further comprises:
a local area network (LAN) card disposed on the test board and configured to communicate with the stacker controller; and
a vector memory configured to store the test program provided from the test controller.

11. The test facility of claim 1, wherein the stacker part further comprises:
a robot configured to transport the test board parts between the stackers; and
a loader/unloader configured to hold the test board parts prior to being transported by the robot.

12. The test facility of claim 1, wherein at least one of the semiconductor devices is configured to perform a built-in self-test.

13. A method of testing semiconductor devices, comprising:
loading a test board part, on which semiconductor devices having a built-in self-test function are mounted, into a stacker part;
providing a test program from a server to the test board part;
performing the built-in self-test on the semiconductor devices; and
outputting a test result obtained from the built-in self-test of the semiconductor devices to the server.

14. The method of claim 13, further comprising providing information about the semiconductor devices mounted on the test hoard part from the stacker part to the server.

15. The method of claim 14, wherein providing the information about the semiconductor devices comprises requesting the server to provide the test program.

16. The method of claim 13, further comprising unloading the test board part from the stacker part.

17. A test facility for testing semiconductor devices, comprising:
a stacker part configured to receive test programs from a server;
first and second test boards disposed in the stacker part, the first test board including first semiconductor devices configured to perform a first built-in test, the second test board including second semiconductor devices configured to perform a second built-in test,
wherein the first and second built-in tests are performed at the same time in response to the test programs received from server.

18. The test facility of claim 17, wherein the first and second semiconductor devices are different from each other.

19. The test facility of claim 17, wherein the first and second test boards are independently operated.

20. The test facility of claim 17, wherein the stacker part further comprises a loader/unloader configured to hold the first and second test boards, a robot configured to move the first and second test boards to a unit stacker and a stacker controller configured to interface between the server and stacker part.
